(19) United States
(12) Patent Application Publication
(10) Pub. No.: US 2018/0062611 A1
(43) Pub. Date: Mar. 1, 2018

(54) RF MODULE INCLUDING SAW DEVICE, METHOD OF MANUFACTURING THE RF MODULE, THE SAW DEVICE, AND METHOD OF MANUFACTURING THE SAW DEVICE

(71) Applicant: WISOL CO., LTD., Gyeonggi-do (KR)

(72) Inventors: Jong Soo HA, Gyeonggi-do (KR); Eun Tae PARK, Gyeonggi-do (KR); Bong Soo KIM, Gyeonggi-do (KR); Jung Hoon HAN, Gyeonggi-do (KR); Chang Dug KIM, Gyeonggi-do (KR)

(21) Appl. No.: 15/681,153

(22) Filed: Aug. 18, 2017

(30) Foreign Application Priority Data
Aug. 26, 2016 (KR) 10-2016-0109528

(51) Int. Cl. H03H 9/02; H05K 1/18; H03H 3/02; H05K 3/32

(52) U.S. Cl. CPC H03H 9/02992; H05K 1/181; H05K 2201/032; H05K 3/32; H05K 2201/10083; H03H 3/02

(57) ABSTRACT

Disclosed is a radiofrequency (RF) module including a surface acoustic wave (SAW) device that includes a piezoelectric substrate, an interdigital transducer (IDT) electrode and an input/output electrode formed on one surface of the piezoelectric substrate, and a bump joined to the input/output electrode, a printed circuit board (PCB) that includes a terminal corresponding to the input/output electrode and on which the SAW device is mounted to join the bump to the terminal, a molding portion that covers the SAW device, and a dam portion that surrounds the IDT electrode, the input/output electrode, and the bump not to allow a molding material that forms the molding portion to penetrate a space in which the IDT electrode, the input/output electrode, and the bump are arranged.

### CROSS-REFERENCE TO RELATED APPLICATION

This application claims priority to and the benefit of Korean Patent Application No. 2016-0109528, filed on Aug. 26, 2016, the disclosure of which is incorporated herein by reference in its entirety.

### FIELD

The present invention relates to a radiofrequency (RF) module including a surface acoustic wave (SAW) device, a method of manufacturing the RF module, the SAW module, and a method of manufacturing the SAW device.

### BACKGROUND

As a telecommunications industry has developed, wireless communication products become gradually miniaturized and acquire high quality and multiple functions. According to this tendency, components used in a wireless communication product, for example, a filter, a duplexer and the like need miniaturization and multiple functions.

As an example of these components, as shown in FIG. 1, a surface acoustic wave (SAW) device includes a piezoelectric substrate 1 that is a piezoelectric single crystal bare chip, a pair of interdigital transducer (IDT) electrodes 2 having a comb-pattern and formed to face each other on a top surface of the piezoelectric substrate 1, and input/output electrodes 3 and 4 connected to the IDT electrodes 2.

When an electric signal is applied to the input electrode 3, a piezoelectric distortion caused by a piezoelectric effect occurs by a length of overlapped parts of the IDT electrodes 2 facing each other, and an SAW transferred to the piezoelectric substrate 1 occurs due to the piezoelectric distortion and is converted into an electric signal output through the output electrode 4. Here, only an electrical signal in a certain frequency band determined by several factors such as intervals, an electrode width or length and the like of the IDT electrodes 2 is passed.

Since features of device are determined by the electrode width, length, and intervals of the IDT electrodes 2 formed on the piezoelectric substrate 1 of the SAW device, when the IDT electrodes 2 are damaged or stained with micro-sized foreign substances such as dust or dirt, the features of device change. Accordingly, structures in various shapes are required to protect the electrodes of the SAW device from an external environment.

FIG. 2 illustrates an example of a structure of an SAW device package 10 for protecting electrodes of the SAW device from an external environment.

As shown in FIG. 2, the SAW device package 10 includes a package substrate 7 on which an SAW device is mounted using a flip chip bonding method and which includes a terminal 6 corresponding to the input/output electrodes 3 and 4 and an encapsulation portion 8 that covers the input/output electrodes 3 and 4, a bump 5 joined to the terminal 6, and the SAW device. A space for an SAW forming area such as the IDT electrodes 2 and the like is provided by the bump 5, and the encapsulation portion 8 protects the SAW forming area from an external environment. Here, materials such as a film type epoxy, a metal, ceramic and the like are used for the encapsulation portion 8. Here, since they are hard materials or soft materials having viscosity at or above a certain level, they may penetrate only the outermost part of the piezoelectric substrate 1 but do not penetrate an internal space thereof in which the bump 5 and the IDT electrodes 2 are arranged.

FIG. 3 illustrates an example of a radiofrequency (RF) module on which the SAW device package 10 is mounted.

Referring to FIG. 3, the SAW device package 10 and other devices 30 and 40 are mounted on a PCB 20 using a surface mount technology (SMT). Here, other devices 30 and 40 may include active elements such as an integrated circuit (IC), an amplifier, a switch, and the like and passive elements such as a resistor, a capacitor, an inductor, and the like. Also, a molding portion 50 that surrounds the SAW device package 10 and in addition other devices 30 and 40 is formed on the PCB 20. As a molding material for the molding portion 50, for example, liquid type epoxy may be used. A material cheaper than a material of the encapsulation portion 8 of the SAW device package 10 is used as the molding material. This is because the molding portion 50 of the RF module needs a large amount of molding material due to a broad covering area compared with the encapsulation portion 8 of the SAW device package 10.

According to the above-described existing RF module, since the encapsulation portion 8 of the SAW device package 10 and the molding portion 50 of the RF module perform structurally similar functions with respect to the SAW device, there is an unnecessary repeated structure. Also, an increase in costs is caused by expensive materials used for the encapsulation portion 8 such as film type epoxy, a metal, ceramic and the like and a process of forming the encapsulation portion 8.

To overcome them, a structure in which an SAW device itself is mounted on the PCB 20 using a flip chip bonding method instead of an SAW device package may be conceived. However, in this case, since the encapsulation portion 8 is not present, a liquid molding material used for the molding portion 50 directly penetrate an SAW forming area such as the IDT electrodes 2. Accordingly, there is generated a limitation in which a space for the SAW forming area is incapable of not only being adequately formed but also being protected from an external environment.

### SUMMARY

It is an aspect of the present invention to provide a radiofrequency (RF) module capable of preventing a liquid molding material used for a molding portion from penetrating a surface acoustic wave (SAW) forming area such as an interdigital transducer (IDT) electrode and the like of an SAW device in a radiofrequency (RF) module having a structure in which the SAW device itself is mounted on a printed circuit board (PCB) using a flip chip bonding method, a method of manufacturing the RF module, an SAW device for the RF module, and a method of manufacturing the SAW device.

According to one aspect of the present invention, an RF module includes an SAW device that includes a piezoelectric substrate, an IDT electrode and an input/output electrode formed on one surface of the piezoelectric substrate, and a bump joined to the input/output electrode, a PCB that includes a terminal corresponding to the input/output electrode and on which the SAW device is mounted to join the bump to the terminal, a molding portion that covers the SAW device, and a dam portion that surrounds the IDT electrode, the input/output electrode, and the bump not to allow a molding material that forms the molding portion to penetrate a space in which the IDT electrode, the input/output electrode, and the bump are arranged.

A material of the bump may include gold or a gold alloy, and a material of the dam portion may include gold or a gold alloy.

A material of the bump may include gold or a gold alloy, and a material of the dam portion may include a resin.

A material of the bump may include tin, a tin alloy, tin-silver, or a tin silver alloy, and a material of the dam portion may include tin, a tin alloy, tin-silver, or a tin silver alloy.

The molding portion may cover the SAW device and in addition other devices mounted on the PCB.

An SAW device may include a piezoelectric substrate, an IDT electrode formed on one surface of the piezoelectric substrate, an input/output electrode formed on the one surface of the piezoelectric substrate, a bump joined to the input/output electrode, and a dam portion that surrounds the IDT electrode, the input/output electrode, and the bump.

A material of the bump may include gold or a gold alloy, and a material of the dam portion may include gold or a gold alloy.

A material of the bump may include gold or a gold alloy, and a material of the dam portion may include a resin.

A material of the bump may include tin, a tin alloy, tin-silver, or a tin silver alloy, and a material of the dam portion may include tin, a tin alloy, tin-silver, or a tin silver alloy.

A height of the dam portion may be greater than a height of the bump from the piezoelectric substrate.

A height of the dam portion may be identical to a height of the bump from the piezoelectric substrate.

According to another aspect of the present invention, a method of manufacturing an RF module includes (a) forming a dam portion that surrounds an IDT electrode and an input/output electrode and a bump joined to the input/output electrode, on an SAW device including a piezoelectric substrate and the IDT electrode and the input/output electrode formed on one surface of the piezoelectric substrate, (b) mounting the SAW device on the PCB including a terminal corresponding to the input/output electrode to join the bump to the terminal and to isolate a space in which the input/output electrode and the bump are arranged in the dam portion from an outside of the dam portion using the dam portion, and (c) forming a molding portion that covers the SAW device.

In the operation (a), a height of the dam portion may be formed to be greater than a height of the bump from the piezoelectric substrate. In the operation (b), the dam portion may be joined to the PCB.

In the operation (a), a height of the dam portion may be formed to be identical to a height of the bump from the piezoelectric substrate and a pattern having the same shape as that of the dam portion may be formed at a part of the PCB corresponding to the dam portion. In the operation (b), the dam portion and the pattern may be joined to each other.

According to still another aspect of the present invention, a method of manufacturing an SAW device includes (a) preparing the SAW device including a piezoelectric substrate and an IDT electrode and an input/output electrode formed on one surface of the piezoelectric substrate and (b) forming a dam portion that surrounds the IDT electrode and the input/output electrode and a bump joined to the input/output electrode.

The operation (b) may include (b1) forming the dam portion that surrounds the IDT electrode and the input/output electrode and (b2) forming the bump joined to the input/output electrode.

The operation (b1) may include forming a plating resist having an opening pattern corresponding to the dam portion to be formed, on the one surface of the piezoelectric substrate, forming the dam portion by plating the opening pattern, and removing the plating resist.

The operation (b1) may include forming the dam portion using a resin through a photolithography process.

The operation (b) may include forming a plating resist having an opening pattern corresponding to the dam portion and the bump to be formed, on the one surface of the piezoelectric substrate, forming the dam portion and the bump by plating the opening pattern, and removing the plating resist.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 illustrates an example of a surface acoustic wave (SAW) device;

FIG. 2 illustrates an example of a structure of an SAW device package for protecting electrodes of the SAW device from an external environment;

FIG. 3 illustrates an example of a radiofrequency (RF) module on which the SAW device package is mounted;

FIG. 4 illustrates an RF module including an SAW device according to one embodiment of the present invention;

FIGS. 5A and 5B are views illustrating a method of manufacturing the SAW device and the RF module including the same according to one embodiment of the present invention;

FIGS. 6A and 6B are views illustrating a method of manufacturing an SAW device and an RF module including the same according to another embodiment of the present invention;

FIGS. 7A, 7B, 7C, and 7D are views illustrating a method of manufacturing the SAW device according to one embodiment of the present invention;

FIGS. 8A, 8B, and 8C are views illustrating a method of manufacturing the SAW device according to another embodiment of the present invention; and

FIGS. 9A and 9B are views illustrating a method of manufacturing an SAW device according to still another embodiment of the present invention.

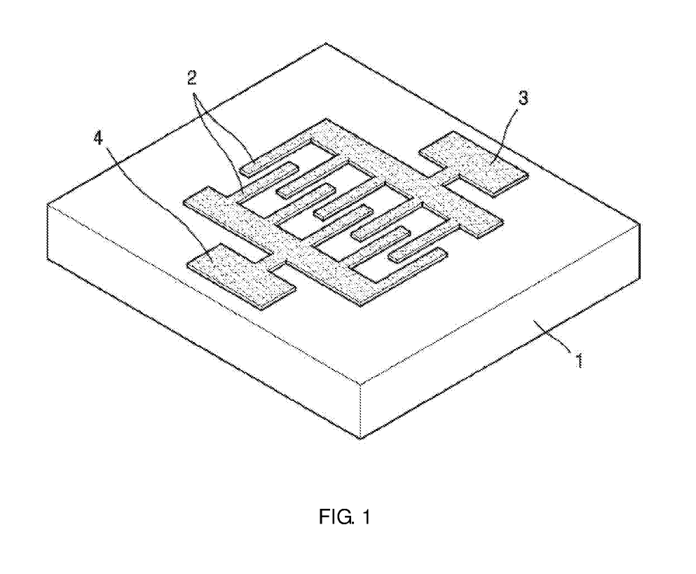

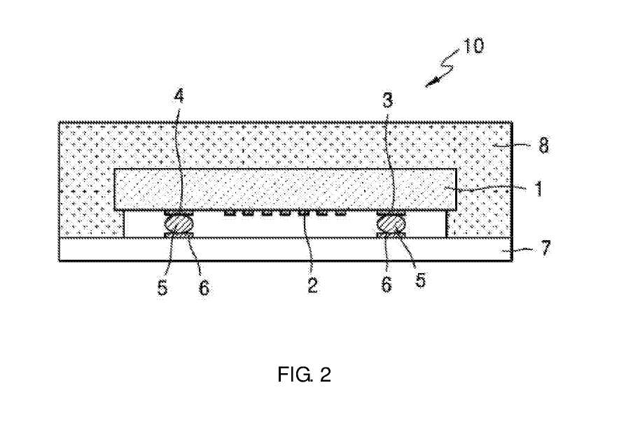

### DETAILED DESCRIPTION

Hereinafter, exemplary embodiments of the present invention will be described in detail with reference to the drawings. Throughout the following description and attached drawings, substantially like components will be referred to as like reference numerals and a repeated description thereof will be omitted. Also, throughout the description of the embodiments of the present invention, a detailed explanation of well-known functions and components of the related art will be omitted when it is deemed that they may unnecessarily obscure the essence of the present invention.

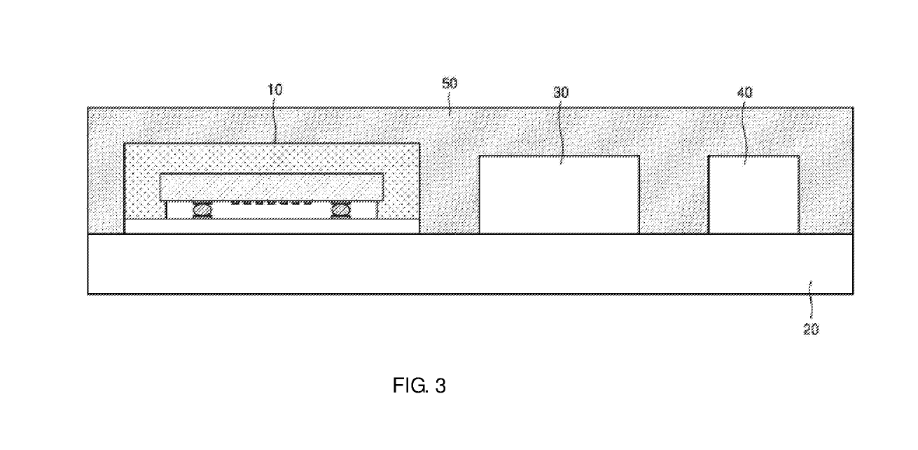

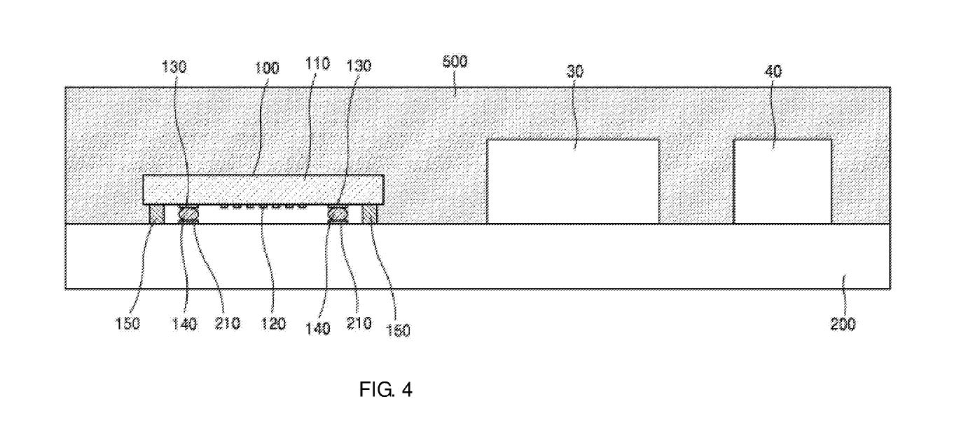

FIG. 4 illustrates a radiofrequency (RF) module including a surface acoustic wave (SAW) device 100 according to one embodiment of the present invention.

Referring to FIG. 4, the RF module according to the embodiment includes the SAW device 100, a printed circuit board (PCB) 200 on which the SAW device 100 is mounted using a flip-chip bonding method, other devices 30 and 40 mounted on the PCB 200, and a molding portion 500 that covers the SAW device 100 and the other devices 30 and 40.

The SAW device 100 includes a piezoelectric substrate 110, an interdigital transducer (IDT) electrode 120, an input/output electrode 130 connected to the IDT electrode 120, and a bump 140 joined to the input/output electrode 130.

The PCB 200 includes a terminal 210 corresponding to the input/output electrode 130 of the SAW device 100, and the SAW device 100 is mounted on the PCB 200 to allow the bump 140 to be joined to the terminal 210.

A molding portion 500 may be formed of a liquid molding material such as epoxy and the like, and a dam portion 150 that surrounds the IDT electrode 120, the input/output electrode 130, and the bump 140 is formed not to allow the molding material to penetrate a space in which the IDT electrode 120, the input/output electrode 130, and the bump 140 are arranged. That is, since the molding material of the molding portion 500 is prevented by the dam portion 150 from penetrating a space between the piezoelectric substrate 110 and the PCB 200, even when the liquid molding material is used, a space for an SAW forming area may be provided and the SAW forming area may be protected from an external environment.

The dam portion 150 may be formed first on the SAW device 100, and the SAW device 100 on which the dam portion 150 is formed may be mounted on the PCB 200. Depending on embodiments, the dam portion 150 may be formed at a position of the PCB 200 on which the SAW device 100 will be mounted and the SAW device 100 may be mounted on the PCB 200 on which the dam portion 150 is formed. Also, depending on embodiments, one part of the dam portion 150 is formed on the SAW device 100 and another part of the dam portion 150 is formed on the PCB 200 in such a way that the SAW device 100 may be mounted and the whole dam portion 150 may be formed.

Generally, the bump 140 may be formed of a material including gold (Au), tin (Sn), tin-silver (SnAg), copper (Cu) or the like. The dam portion 150 may be formed of the same material as or a different material from that of the bump 140 or may be formed of a resin.

When the material of the dam portion 150 is a metal, the material may include Au, an Au alloy, Sn, an Sn alloy, SnAg, or a SnAg alloy.

When both the bump 140 and the dam portion 150 are formed of Au or an Au alloy, the SAW device 100 may be mounted on the PCB 200 using an ultrasonic thermocompression bonding method. Here, the bump 140 is joined to the terminal 210 and simultaneously the dam portion 150 formed first on the SAW device 100 is joined to the PCB 200, the dam portion 150 formed first on the PCB 200 is joined to the SAW device 100, or one part of the dam portion 150 formed on the SAW device 100 and another part of the dam portion 150 formed on the PCB 200 are joined to each other through ultrasonic thermocompression bonding.

When the bump 140 is formed of Au or an Au alloy and the dam portion 150 is formed of a resin, the SAW device 100 may be mounted on the PCB 200 using an ultrasonic thermocompression bonding method. Here, the bump 140 is joined to the terminal 210 and simultaneously the dam portion 150 formed first on the SAW device 100 is joined to the PCB 200, the dam portion 150 formed first on the PCB 200 is joined to the SAW device 100, or one part of the dam portion 150 formed on the SAW device 100 and another part of the dam portion 150 formed on the PCB 200 are joined to each other through ultrasonic thermocompression bonding. That is, the resin that forms the dam portion 150 is temporarily melted by applied heat and then cured again, thereby forming a joint portion.

When both the bump 140 and the dam portion 150 are formed of Sn, an Sn alloy, SnAg, or an SnAg alloy, the SAW device 100 may be mounted on the PCB 200 using a thermocompression bonding method. Here, the bump 140 is joined to the terminal 210 and simultaneously the dam portion 150 formed first on the SAW device 100 is joined to the PCB 200, the dam portion 150 formed first on the PCB 200 is joined to the SAW device 100, or one part of the dam portion 150 formed on the SAW device 100 and another part of the dam portion 150 formed on the PCB 200 are joined to each other through thermocompression bonding.

Since an area occupied by the dam portion 150 is considerably larger than that of the bump 140, when both the bump 140 and the dam portion 150 are formed of Au or an Au alloy, material costs may relatively increase. However, when the bump 140 is formed of Au or an Au alloy and the dam portion 150 is formed of a resin or both the bump 140 and the dam portion 150 are formed of Sn, an Sn alloy, SnAg, or an SnAg alloy, there is an advantage of less material costs.

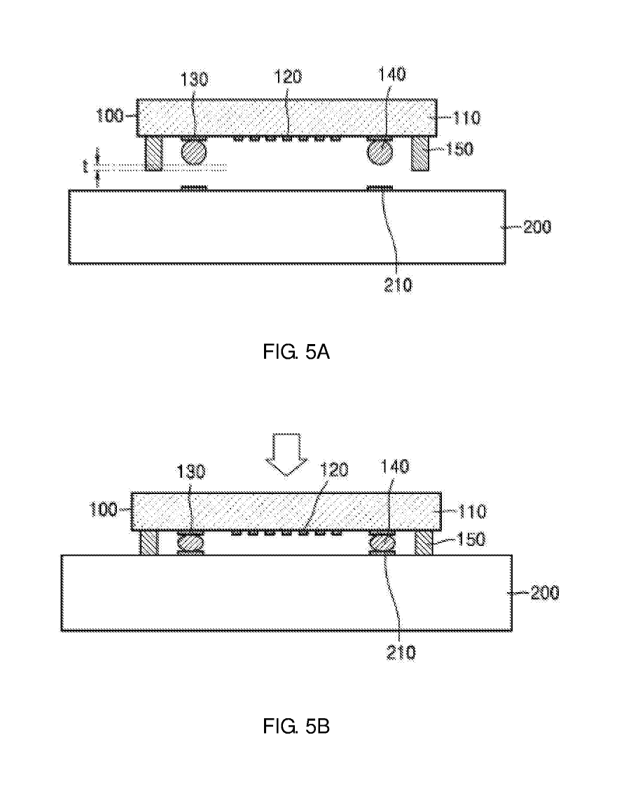

FIGS. 5A and 5B are views illustrating a method of manufacturing the SAW device 100 and the RF module including the same according to one embodiment of the present invention.

Referring to FIG. 5A, the SAW device 100 according to the embodiment includes the piezoelectric substrate 110, the IDT electrode 120 formed on one surface of the piezoelectric substrate 110, the input/output electrode 130 formed on the one surface of the piezoelectric substrate 110 and connected to the IDT electrode 120, the bump 140 joined to the input/output electrode 130, and the dam portion 150 that surrounds the IDT electrode 120, the input/output electrode 130, and the bump 140.

Meanwhile, the terminal 210 corresponding to the input/output electrode 130 of the SAW device 100 is provided on the PCB 200.

As shown in FIG. 5B, the SAW device 100 is mounted on the PCB 200 while the bump 140 is joined to the terminal 210 and a space in the dam portion 150 in which the input/output electrode 130 and the bump 140 are arranged is isolated from an outside of the dam portion 150 by the dam portion 150. As described above, since the SAW device 100 is mounted on the PCB 200 using an ultrasonic thermocompression bonding method or a thermocompression bonding method, the bump 140 is deformed by heat and pressure to be flatter than an original shape shown in FIG. 5A. Here, the dam portion 150 is also deformed to be flatter than an original shape shown in FIG. 5A, like the bump 140.

Also, as shown in FIG. 4, the molding portion 500 that covers the SAW device 100 and the other devices 30 and 40 is formed using a molding material.

As shown in FIG. 5A, a height of the dam portion 150 formed at the piezoelectric substrate 110 is greater than a height of the bump 140 from the piezoelectric substrate 110, that is, a sum of a thickness of the input/output electrode 130 and a thickness of the bump 140. A difference in the heights is formed considering the terminal 210 of the PCB 200. This is for adequately intimate joining with the PCB 200 to allow the dam portion 150 to prevent the molding material that will form the molding portion 500 from penetrating when the SAW device 100 is mounted on the PCB 200. Referring to FIG. 5A, a height difference t may be identical or approximate to a thickness of the terminal 210 of the PCB 200. However, a deformation degree of the bump 140 may differ from a deformation degree of the dam portion 150 depending on materials of the bump 140 and the dam portion 150 or depending on a process condition such as a bonding method and the like, the height difference t may be determined to be an adequate value considering the materials and the process condition.

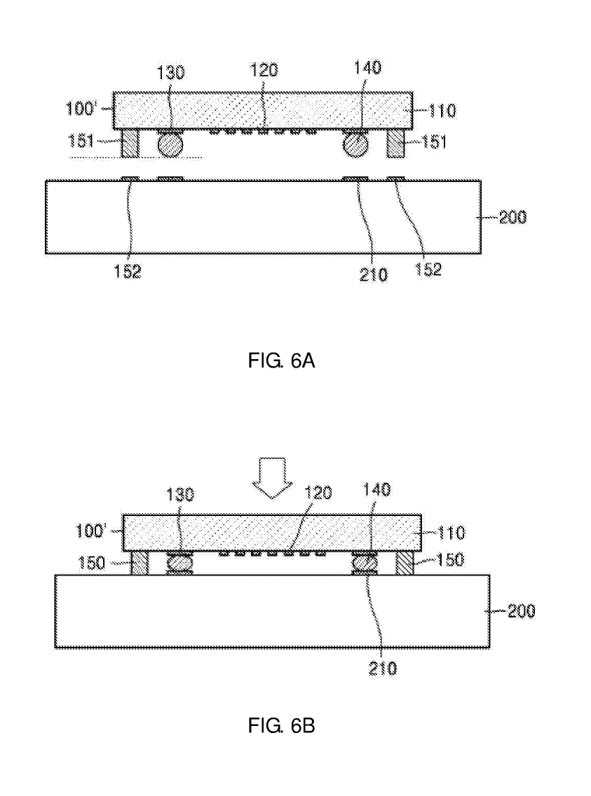

FIGS. 6A and 6B are views illustrating a method of manufacturing an SAW device 100′ and an RF module including the same according to another embodiment of the present invention.

Referring to FIG. 6A, the SAW device 100′ according to the embodiment includes the piezoelectric substrate 110, the IDT electrode 120 formed on one surface of the piezoelectric substrate 110, the input/output electrode 130 formed on the one surface of the piezoelectric substrate 110 and connected to the IDT electrode 120, the bump 140 joined to the input/output electrode 130, and a dam portion 151 that surrounds the IDT electrode 120, the input/output electrode 130, and the bump 140.

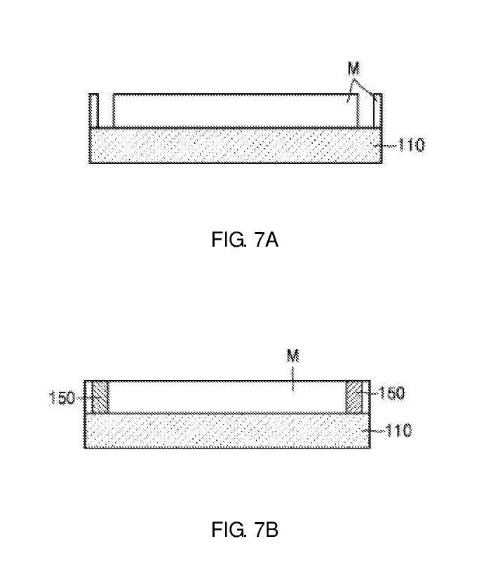

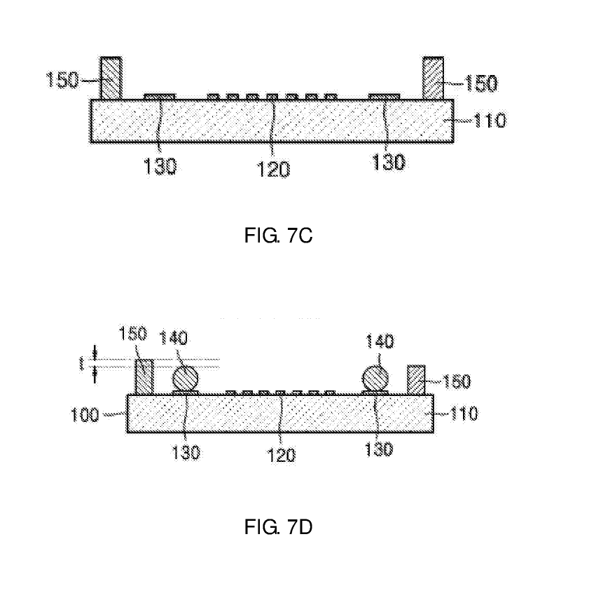

Meanwhile, the terminal 210 corresponding to the input/output electrode 130 of the SAW device 100′ is formed on the PCB 200 and a pattern 152 having the same shape as that of the dam portion 151 is also formed at a part corresponding to the dam portion 151 of the SAW device 100′. The dam portion 151 and the pattern 152 in FIG. 6A correspond to one part and the other part that form the dam portion 150 of FIG. 6B, respectively. The pattern 152 may be formed on the PCB 200 using a method similar to that of forming the dam portion 150 which will be described below with reference to FIGS. 7A to 9B and may have the same material as that of the dam portion 151.

As shown in FIG. 6B, the SAW device 100′ is mounted on the PCB 200 while the bump 140 is joined to the terminal 210 and a space in the dam portion 150 in which the input/output electrode 130 and the bump 140 are arranged is isolated from an outside of the dam portion 150 by the dam portion 150 formed by joining the dam portion 151 of the SAW device 100′ to the pattern 152 of the PCB 200. As described above, since the SAW device 100 is mounted on the PCB 200 using an ultrasonic thermocompression bonding method or a thermocompression bonding method, the bump 140 is deformed by heat and pressure to be flatter than an original shape shown in FIG. 6A. Here, the dam portion 151 is also deformed to be flatter than an original shape shown in FIG. 6A, like the bump 140.

Also, as shown in FIG. 4, the molding portion 500 that covers the SAW device 100 and the other devices 30 and 40 is formed using a molding material.

As shown in FIG. 6A, a height of the dam portion 151 formed at the piezoelectric substrate 110 is substantially identical to a height of the bump 140 from the piezoelectric substrate 110, that is, a sum of a thickness of the input/output electrode 130 and a thickness of the bump 140. Meanwhile, the pattern 152 corresponding to the dam portion 151 and formed on the PCB 200 has a thickness substantially identical to that of the terminal 210. The dam portion 150 is formed by joining the dam portion 151 to the pattern 152, thereby preventing penetration of the molding material that will form the molding portion 500. Since a deformation degree of the bump 140 and a deformation degree of the dam portion 151 may differ from each other depending on a material of the bump 140 and a material of the dam portion 151 or a process condition such as a bonding method and the like, a slight difference may be present between a height of the dam portion 151 and a height of the bump 140 from the piezoelectric substrate 110 considering the materials and the process condition.

FIGS. 7A to 7D are views illustrating a method of manufacturing the SAW device 100 according to one embodiment of the present invention. The embodiment may be applied to a case in which a material of the dam portion 150 is a metal of the same material or a different material from that of the bump 140.

First, an SAW device including the piezoelectric substrate 110, the IDT electrode 120 formed on one surface of the piezoelectric substrate 110, and the input/output electrode 130 is prepared.

As shown in FIG. 7A, a plating resist M having an opening pattern corresponding to the dam portion 150 to be formed is formed on one surface of the piezoelectric substrate 110. Here, a height of the plating resist M is formed to be identical to a height of the dam portion 150 to be formed.

After the dam portion 150 is formed by plating the opening pattern of the plating resist M as shown in FIG. 7B, the plating resist M is removed as shown in FIG. 7C.

Also, as shown in FIG. 7D, the bump 140 is formed by joining a bump ball to the input/output electrode 130. Here, joining of the bump 140 may be formed using an ultrasonic thermocompression bonding method in case of Au or an Au alloy or using a thermocompression bonding method in case of Sn, an Sn alloy, SnAg, or an SnAg alloy.

FIGS. 7A to 7D illustrate a method of manufacturing the SAW device 100 in which a height of the dam portion 150 is formed to be greater than a height of the bump 140 from the piezoelectric substrate 110 as shown in FIG. 5A. Here, a height of the plating resist M is formed to be greater than the height of the bump 140 from the piezoelectric substrate 110. However, the method shown in FIGS. 7A to 7D may be applied to a method of manufacturing the SAW device 100′ in which a height of the dam portion 151 is formed to be substantially identical to a height of the bump 140 from the piezoelectric substrate 110 as shown in FIG. 6A. Here, a height of the plating resist M is formed to be identical to the height of the bump 140 from the piezoelectric substrate 110.

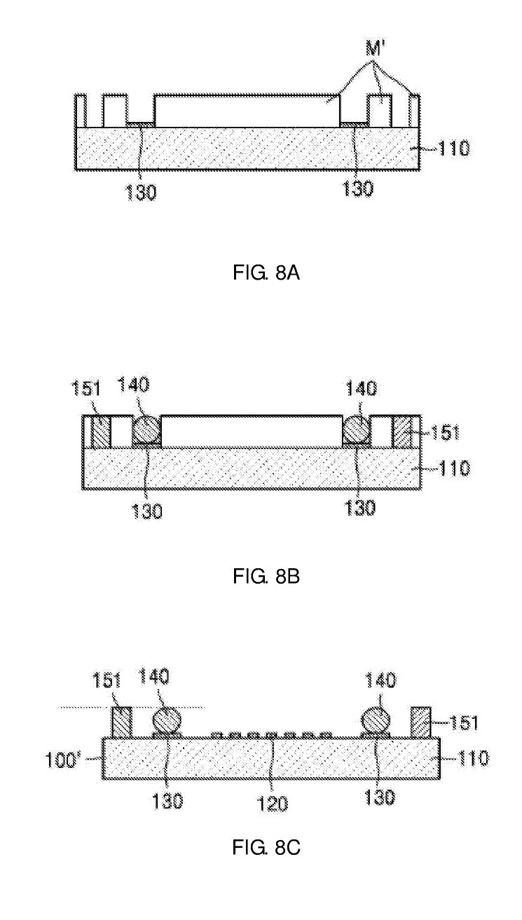

FIGS. 8A to 8C are views illustrating a method of manufacturing the SAW device 100′ according to another embodiment of the present invention. The embodiment may be a method of manufacturing the SAW device 100′ in which a material of the dam portion 151 is a metal of the same material as that of the bump 140 and a height of the dam portion 151 is substantially identical to a height of the bump 140 from the piezoelectric substrate 110 as shown in FIG. 6A.

As shown in FIG. 8A, a plating resist M′ having an opening pattern corresponding to the dam portion 150 and the bump 140 to be formed is formed on one surface of the piezoelectric substrate 110.

As shown in FIG. 8, the dam portion 151 and the bump 140 are formed at the same time by plating the opening pattern of the plating resist M′.

Also, as shown in FIG. 8C, when the plating resist M′ is removed, the SAW device 100′ with the dam portion 151 and the bump 140 formed thereon is completed.

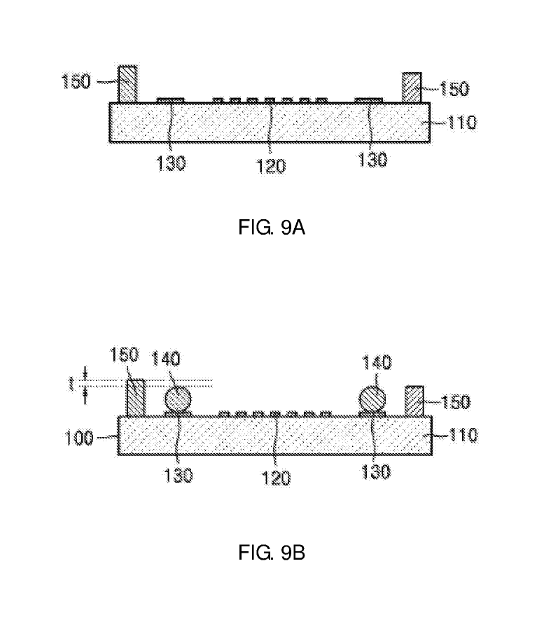

FIGS. 9A and 9B are views illustrating a method of manufacturing an SAW device according to still another embodiment of the present invention. The embodiment may be applied to a case in which a material of the dam portion 151 is a resin.

As shown in FIG. 9A, the dam portion 150 is formed using a resin material through a photolithography process.

Also, as shown in FIG. 9B, the bump 140 is formed by joining a bump ball to the input/output electrode 130. Here, joining of the bump 140 may be formed using an ultrasonic thermocompression bonding method in case of Au or an Au alloy or using a thermocompression bonding method in case of Sn, an Sn alloy, SnAg, or an SnAg alloy.

FIGS. 9A and 9B illustrate a method of manufacturing the SAW device 100 in which a height of the dam portion 150 is formed to be greater than a height of the bump 140 from the piezoelectric substrate 110 as shown in FIG. 5A. However, the method shown in FIGS. 9A and 9B may be applied to the method of manufacturing the SAW device 100′ in which the height of the dam portion 151 is formed to be substantially identical to the height of the bump 140 from the piezoelectric substrate 110 as shown in FIG. 6A.

According to the embodiments of the present invention, there is an effect of preventing a liquid molding material used for a molding portion from penetrating an SAW forming area such as an IDT electrode and the like of an SAW device in an RF module having a structure in which the SAW device itself is mounted on a PCB using a flip chip bonding method.

Also, since it is unnecessary to use an encapsulation portion of an expensive material required in an SAW package structure, there is an effect of reducing material costs and process costs.

While the exemplary embodiments of the present invention have been described above, it should be understood by one of ordinary skill in the art that the present invention may be modified without departing from the essential features of the present invention. Therefore, the disclosed embodiments should be considered not in a limitative point of view but in a descriptive point of view. It should be appreciated that the scope of the present invention is defined by the claims not by the above description and includes all differences within the equivalent scope thereof.

What is claimed is:

1. A radiofrequency (RF) module comprising:
a surface acoustic wave (SAW) device that comprises a piezoelectric substrate, an interdigital transducer (IDT) electrode and an input/output electrode formed on one surface of the piezoelectric substrate, and a bump joined to the input/output electrode;
a printed circuit board (PCB) that comprises a terminal corresponding to the input/output electrode and on which the SAW device is mounted to join the bump to the terminal;
a molding portion that covers the SAW device; and
a dam portion that surrounds the IDT electrode, the input/output electrode, and the bump not to allow a molding material that forms the molding portion to penetrate a space in which the IDT electrode, the input/output electrode, and the bump are arranged.

2. The RF module of claim 1, wherein a material of the bump comprises gold or a gold alloy, and
wherein a material of the dam portion comprises gold or a gold alloy.

3. The RF module of claim 1, wherein a material of the bump comprises gold or a gold alloy, and
wherein a material of the dam portion comprises a resin.

4. The RF module of claim 1, wherein a material of the bump comprises tin, a tin alloy, tin-silver, or a tin silver alloy, and
wherein a material of the dam portion comprises tin, a tin alloy, tin-silver, or a tin silver alloy.

5. The RF module of claim 1, wherein the molding portion covers the SAW device and in addition other devices mounted on the PCB.

6-11. (canceled)

12. A method of manufacturing an RF module, comprising:
(a) forming a dam portion that surrounds an IDT electrode and an input/output electrode and a bump joined to the input/output electrode, on an SAW device including a piezoelectric substrate and the IDT electrode and the input/output electrode formed on one surface of the piezoelectric substrate;
(b) mounting the SAW device on the PCB including a terminal corresponding to the input/output electrode to join the bump to the terminal and to isolate a space in which the input/output electrode and the bump are arranged in the dam portion from an outside of the dam portion using the dam portion; and
(c) forming a molding portion that covers the SAW device.

13. The method of claim 12, wherein a height of the dam portion is formed to be greater than a height of the bump from the piezoelectric substrate in the operation (a), and
wherein the dam portion is joined to the PCB in the operation (b).

14. The method of claim 12, wherein a height of the dam portion is formed to be identical to a height of the bump from the piezoelectric substrate and a pattern having the same shape as that of the dam portion is formed at a part of the PCB corresponding to the dam portion in the operation (a), and
wherein the dam portion and the pattern are joined to each other in the operation (b).

15-19. (canceled)
